(19) United States
(12) Patent Application Publication
(10) Pub. No.: US 2026/0169041 A1
(43) Pub. Date: Jun. 18, 2026

(54) Circuit Check for Monitoring Isolation Resistance

(71) Applicant: Vitesco Technologies USA, LLC, Auburn Hills, MI (US)

(72) Inventor: Jacky Yutsai Wu, Oxford, MI (US)

(73) Assignee: Vitesco Technologies USA, LLC, Auburn Hills, MI (US)

(21) Appl. No.: 18/978,993

(22) Filed: Dec. 12, 2024

(51) Int. Cl. G01R 27/02; B60L 3/00; G01R 31/52

(52) U.S. Cl. CPC G01R 27/025; B60L 3/0069; G01R 31/52

(57) ABSTRACT

A method of circuit check for isolation monitoring is provided. The method includes providing an isolation monitoring circuit to measure isolation resistance between high voltage domain and vehicle chassis and providing a test switch being part of the isolation monitoring circuit. The method also includes providing a sub-switch-circuit having a chassis switch, a constant current source, a resistor positioned between the chassis switch, and a chassis ground. The test switch is movable between a first test switch position and a second test switch position. The method also includes instructing the test switch to move to a first position. In addition, the method includes determining a current source voltage, and determining a position of the test switch based on the current source voltage.

### TECHNICAL FIELD

The disclosure relates to a circuit that provides a circuit check for monitoring isolation resistance in electric vehicles and in hybrid electric vehicles.

### BACKGROUND

Electric vehicles (EVs) and hybrid electrical vehicles (HEVs) include a low-voltage system and high-voltage batteries. Typically, the high-voltage batteries have a nominal voltage within the range 300-800 volts used to power an electrical motor. The high-voltage batteries are electrically insulated from the vehicle body, i.e., the chassis. A negative battery pole in the low-voltage system of the vehicle is connected to chassis ground as is common in vehicles. Due to the nature of EVs and HEVs, transmission of high voltages between circuits can drive electric shock to personnel or equipment.

EVs and HEVs generally include a battery management system (BMS) that is dedicated to managing the vehicle's high-voltage battery that includes an assembly of battery cells configured to enable delivery of targeted range voltage and current for a duration of time. In addition to monitoring the batteries, the BMS module provides battery protection, estimates the batteries'operational states, optimizes battery performance, and reports operational status of the battery to other devices. Furthermore, the BMS is configured to monitor the isolation resistance of the vehicle to prevent electric shocks to personnel or equipment. Isolation resistance is the resistances between the terminals of the vehicle's high-voltage battery pack with respect to the vehicle chassis. EV and HEV vehicles, which use high-power large-capacity batteries, must maintain proper isolation between low-voltage electric devices and the high-voltage batteries. If a good isolation is not maintained, several problems may occur. For example, a leakage current may cause an unexpected discharge of the batteries or malfunction of the electronics supported by the vehicle. The leakage current may give a fatal electric shock to a person.

FIG. 1A shows a first known topology 100a and FIG. 1B shows a second known topology 100b of isolation monitoring circuits 110a, 110b for monitoring the isolation resistance of a battery pack 102 supported by an EV vehicle or an HEV vehicle. The topologies 100, 100a, 100b are designed to monitor positive isolation resistance 104p between high voltage positive V+and chassis ground 106 and also negative isolation resistance 104n between the high voltage negative V− and chassis ground 106. If low resistance condition is detected, the main contactors 120p, 120n or another safety protection device will activate to cutoff the high voltage. As a result, it ensures no leakage current flows from the high-voltage V+ or V− to the lower-voltage ground (chassis) 106, preventing any potential safety hazards to a person.

The conventional way of monitoring isolation resistance 104, 104p, 104n is to introduce the test resistors 112p, 112n and test switch 114p, 114n between high voltage positive V+ and chassis ground 106 and between high voltage negative V− and chassis ground 106 respectively as can be shown in FIGS. 1A and 1B. The BMS module, which includes the isolation monitoring circuits 110a, 110b, measures the degree of isolation resistances 104p, 104n from the traction battery high voltage domain V+, V− to the low voltage chassis ground 106. It is noted that the isolation resistances 104p, 104n are parasitic ohmic resistances and not physical resistors. Each shown topology includes main contactors 120, 120p, 120n that are either open or closed. These main contactors are used to connect/disconnect the high-voltage battery to the vehicle loads like traction motor or OBC (on-board charger). When the main contactors 120, 120p, 120p are open, the isolation monitoring circuit 110, 110a, 110b measures isolation breaches at the side of the traction battery 102. When the main contactors 120, 120a, 120b are closed, the isolation monitoring circuit 110, 110a, 110b measures isolation breaches at the high voltage battery side V+ and HV loads side combined (i.e., combined 104p, 104n) in parallel. This measurement is performed both when the contactors 120, 120p, 120n are open and when they are closed. This is to ensure that there is no leakage current flowing from high voltage domain V+, V− to lower voltage ground 106 (chassis) to cause any safety issue to a person. The monitoring function is based on the principle of a voltage divider.

By controlling the two test switches 114p, 114n, the two test resistors 112p, 112n can be applied in parallel to positive isolation resistance 104p or negative isolation resistance 104n. This causes voltage changes of the chassis voltage with respect to high voltage negative V− and high voltage positive V+ respectively. Additionally, while commending the two test switches 114p, 114n to open and close, the ohmic resistance of each of the two test resistors 112p, 112n may be calculated using a transfer function according to the voltage reading by the converter 118 (i.e., ADC) and the voltage of the high voltage battery.

By doing this and combining with the voltage the measurement from high voltage battery pack 102, the BMS can calculate the positive isolation resistance 104p and the negative isolation resistance 104n.

During isolation monitoring, the BMS checks that the two test switches 114p, 114n are functioning as intended. The known method of checking the circuit (also known as isolation monitoring circuit check) is to utilize the voltage difference while closing or opening the test switch 114p, 114n. However, this method has limitations. When one of the positive isolation resistor 104p and the negative isolation resistance 104n has severe fault (<100K Ω) or perfect isolation (≈infinite Ω), a voltage difference cannot be observed by the converter 118 (i.e., ADC) while closing or opening the test switch 114, 114p, 114n. This will lead to an uncertain condition for isolation monitoring. Therefore, there is a need for an improved isolation monitoring circuit check for accurately and thoroughly detecting a leakage current of a battery.

### SUMMARY

One aspect of the disclosure provides a method of circuit check for isolation monitoring. The method includes providing an isolation monitoring circuit to measure isolation resistance between high voltage domain and vehicle chassis. The method includes providing a test switch being part of the isolation monitoring circuit. In some examples, the test switch includes a positive test switch and a negative test switch. The test switch is movable between a first test switch position (i.e., close or open position) and a second test switch position (i.e., the other one of the close or open position). The method includes providing a sub-switch-circuit. The sub-switch-circuit includes a chassis switch, a constant current source, a resistor positioned between the chassis switch, and a chassis ground. The method includes instructing the test switch, to move to a first position. The method also includes determining a current source voltage. Additionally, the method includes determining a position of the test switch based on the current source voltage.

Implementations of this aspect of the disclosure may include one or more of the following optional features. In some implementations, the method includes instructing the chassis switch to move to an OPEN position and enabling the constant current source. In addition, the method includes measuring a resistor voltage of the resistor. When the resistor voltage is equal to zero, the method includes determining that the chassis switch is in an OPEN position.

In some implementations, the method includes instructing the chassis switch to move to a CLOSE position and enabling the constant current source. Furthermore, the method includes measuring a resistor voltage of the resistor. When the resistor voltage is not equal to zero, the method includes determining that the chassis switch is in the CLOSE position.

In some examples, when the current source voltage is equal to zero, the method includes determining that the test switch is in an OPEN position: if the first test switch position is an OPEN position, the test switch is confirmed in the OPEN position, and if the first test switch position is a CLOSE position, the test switch is stuck in the OPEN position.

In some implementations, when the current source voltage is not equal to zero, the method includes determining that the test switch is in a CLOSE position: if the first position is an OPEN position, the test switch is stuck in the CLOSE position, and if the first position is a CLOSE position, the test switch is confirmed in the CLOSE position.

In some examples, the method includes disabling the constant current source before determining the current source voltage.

Another aspect of the disclosure provides a circuit for isolation monitoring and circuit checking. The circuit includes an isolation monitoring circuit to measure isolation resistance between high voltage domain and vehicle chassis. The circuit also includes a test switch that is part of the isolation monitoring circuit. The test switch includes a positive test switch and a negative test switch. The test switch is movable between a first test switch position (close/open) and a second test switch position (closed/open). The circuit also includes a sub-switch-circuit having a chassis switch, a constant current source, a resistor positioned between the chassis switch, and a chassis ground. Additionally, the circuit includes a controller in communication with the isolation monitoring circuit and the sub-switch-circuit. The controller is configured to instruct the test switch to move to a first position, determine a current source voltage, and determine a position of the test switch based the current source voltage.

Implementations of this aspect of the disclosure may include one or more of the following optional features. In some implementations, the controller is further configured to instruct the chassis switch to move to an OPEN position, enable the constant current source, and measure a resistor voltage of the resistor. When the resistor voltage is equal to zero, the controller determines that the chassis switch is in an OPEN position.

In some examples, the controller is further configured to instruct the chassis switch to move to a CLOSE position, enable the constant current source, and measure a resistor voltage of the resistor. When the resistor voltage is not equal to zero, the controller determines that the chassis switch is in the CLOSE position.

When the current source voltage is equal to zero, the controller may determine that the test switch is in an open position. Where if the first test switch position is an OPEN position, the test switch is confirmed in the OPEN position, and if the first test switch position is a CLOSE position, the test switch is stuck in the OPEN position.

In some implementations, when the current source voltage is not equal to zero, the controller determines that the test switch is in a close position. Where if the first position is an OPEN position, the test switch is stuck in the close position, and if the first position is a CLOSE position, the test switch is confirmed in the CLOSE position.

In some examples, the controller is further configured to disable the constant current source before determining the current source voltage.

The details of one or more implementations of the disclosure are set forth in the accompanying drawings and the description below. Other aspects, features, and advantages will be apparent from the description and drawings, and from the claims.

### DESCRIPTION OF DRAWINGS

FIGS. 1A and 1B are schematic views of prior art isolation resistance monitoring circuits.

FIG. 2 is a schematic view of an exemplary circuit for isolation resistance monitoring.

FIGS. 3A-3C are schematic views of an exemplary arrangement of operations of a method for monitoring the isolation resistance of a circuit.

FIG. 4 is a schematic view of another exemplary arrangement of operations of a method for monitoring the isolation resistance of a circuit.

Like reference symbols in the various drawings indicate like elements.

### DETAILED DESCRIPTION

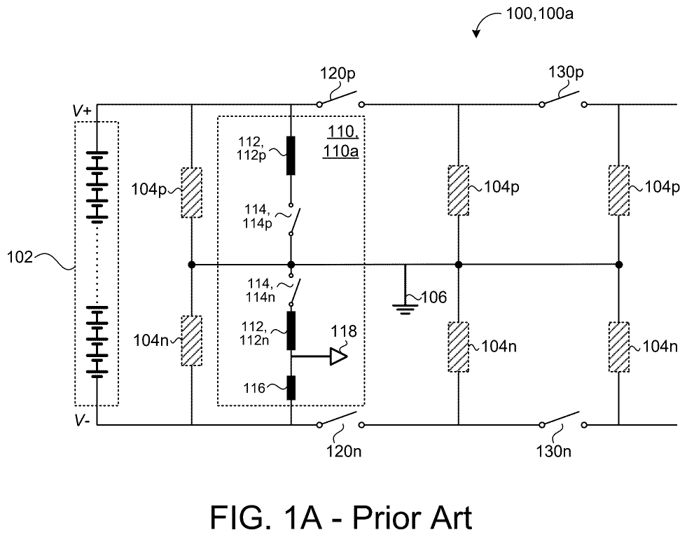

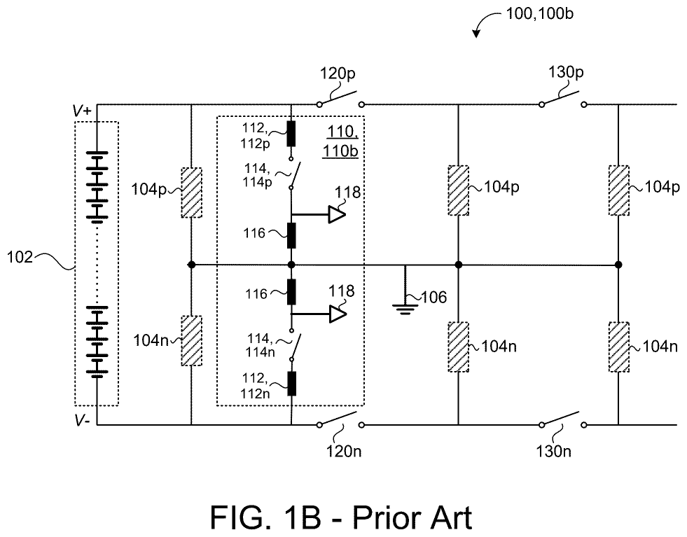

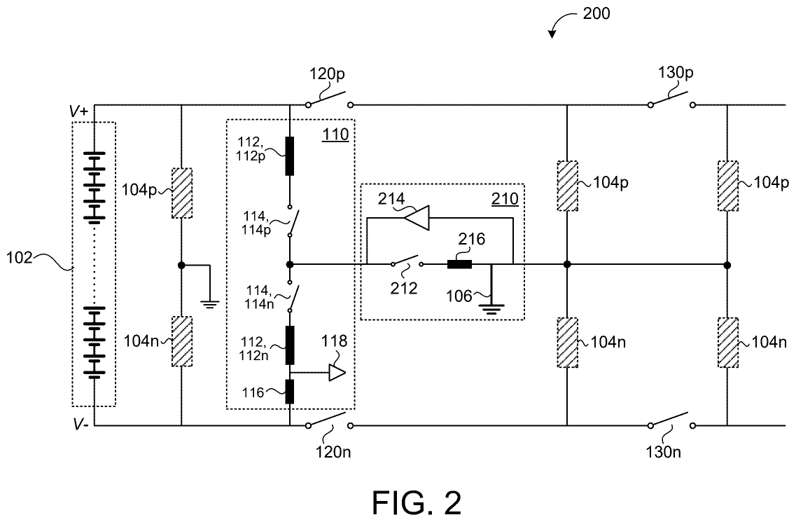

FIG. 2 shows a circuit topology 200 that overcomes the deficiencies of the topologies described in FIGS. 1A and 1B by adding a sub-switch-circuit 210 that allows the isolation monitoring circuit 110 to perform circuit check without being influenced by either severe fault (either 104p or 104n<100K Ω) or perfect isolation condition (either 104p or 104n≈infinite Ω). The same concept can be applied to FIG. 1A.

The circuit topology 200 includes an isolation monitoring circuit 110 similar to the one described in FIG. 1A, but any other circuit combination for isolation monitoring may be used such as, but not limited to, the one described in FIG. 1B, for example. The isolation monitoring circuit 110 is part of the internal function of the BMS (Battery Management System) and monitors the isolation resistance of a battery back 102 supported by an EV or HEV vehicle. As previously mentioned, the isolation monitoring circuit 110 monitors positive isolation resistance 104p between high voltage positive V+ and chassis ground 106 and also negative isolation resistance 104n between the high voltage negative V− and chassis ground 106. The isolation monitoring circuit 110 detects any leakage current from flowing from the high voltage V+ to the lower voltage ground 106 (chassis).

The isolation monitoring circuit 110 includes the test resistors 112p, 112n and test switch 114p, 114n between the high voltage positive V+and the chassis ground 106 and between the high voltage negative V− and the chassis ground 106 to monitor the isolation resistance 104, 104p, 104n.

The sub-switch-circuit 210 enables the isolation monitoring circuit 110 to perform circuit check without the influence from either serve isolation fault or perfect isolation conditions. The sub-switch-circuit 210 includes a chassis switch 212 positioned between the isolation monitoring circuit 110 and the chassis ground 106. The sub-switch-circuit 210 also includes a constant current source 214, such as, but not limited to a diode. The sub-switch-circuit 210 also includes a resistor 216 positioned between the chassis switch 212 and the chassis ground 106. The constant current source 214 provides a current source for the circuit check of the chassis switch 212. By opening the chassis switch 212 of the sub-switch-circuit 210, the test resistors 112p, 112n of the isolation monitoring circuit 110 can be separated from parasitic ohmic resistances 104, 104p, 104n. As such, the current source 214 of the sub-switch-circuit 210 performs circuit check for the chassis switch 212 by enable the current source 214 allowing the current flow through resistor 216 to create a voltage drop across the resistor 216. If no voltage drop across resistor 216, then chassis switch 212 is open. If voltage drop across resistor 216, then chassis switch 212 is close.

During isolation monitoring, the BMS triggers a circuit check by monitoring the ADC 118 voltage output while both test switches 114p, 114n open and close. The ADC voltage output is indicative of a voltage difference between test switches 114p, 114n open and close. When the ADC 118 does not detect a voltage difference when the test switches 114p, 114n open and close, then the test switches 114p, 114n are stuck in either open position or close position, or a severe isolation fault has occurred. In this case, the chassis switch 212 is open to separate one of the test resistors 112p, 112n from the isolation resistance 104p, 104n, allowing the circuit to perform circuit check without the influence from severe isolation fault. Following, the constant current source 214 performs a circuit check for the chassis switch 212.

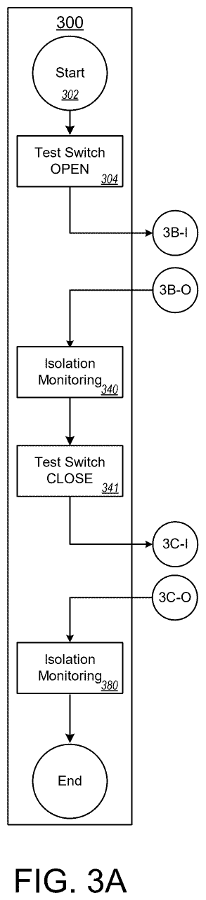

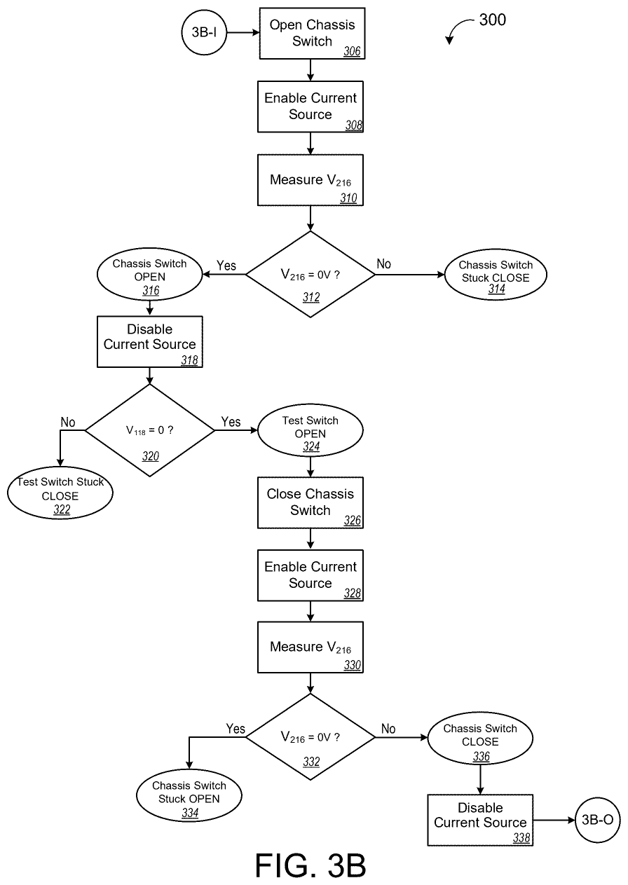

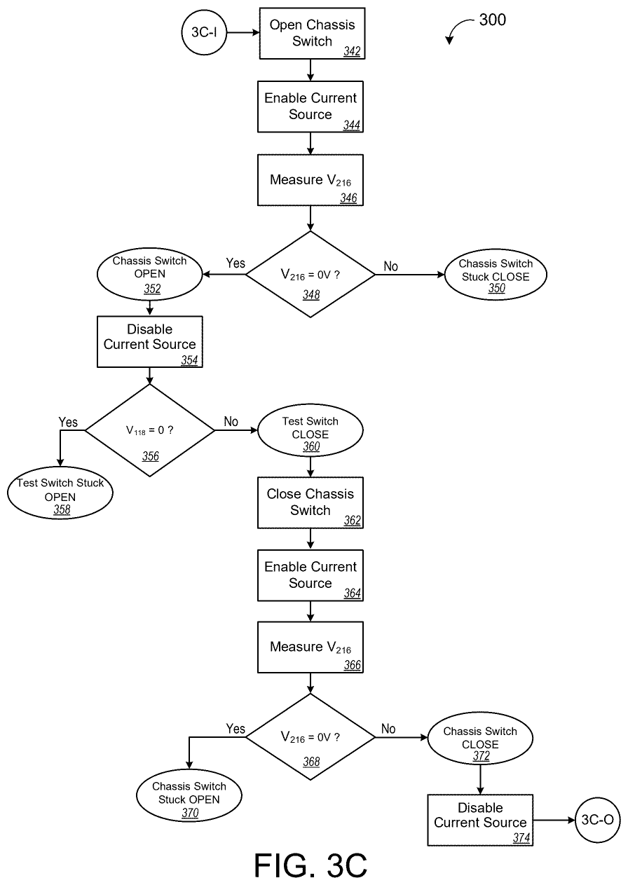

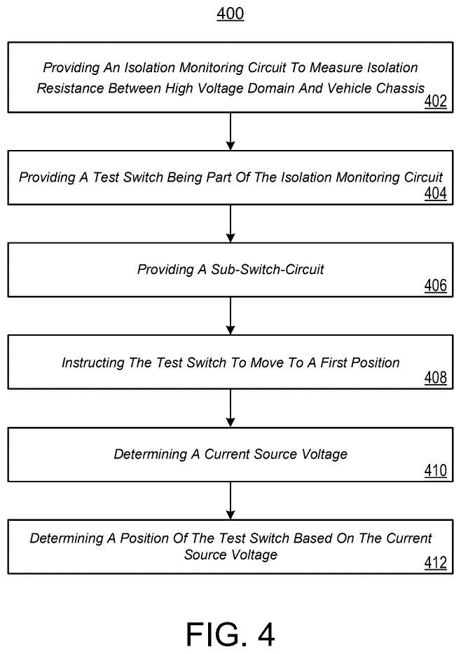

FIGS. 3A-3C show a method 300 for isolation monitoring and circuit check of the topology 200 shown in FIG. 2. This method 300 is performed both when the contactors 120 are open and when they are closed to ensure that there is no leakage current flowing from high voltage domain V+, V− to lower voltage ground 106 (chassis) to cause any safety issue to a person. The method 300 includes opening the test switch 114, 114p, 114n and then closing the test switch 114, 114p, 114n to determine if the circuit topology 200 is performing a circuit check without being influenced from either severe isolation fault or perfect isolation conditions and to determine if any of the test switches 114, 114p, 114n are stuck in either and open or closed positions. However, the method 300 may also start with the test switch 114, 114p, 114n being closed then opening the test switch 114, 114p, 114n.

At block 302, the BMS initiates the method 300 for isolation monitoring and circuit check of the topology 200 shown in FIG. 2. In some examples, the BMS includes a controller (not shown) that executes the method steps. The controller may be in communication with the isolation monitoring circuit 110 and the sub-switch-circuit 210. At block 304, the method 300 includes instructing one of the test switches 114p, 114n to be in a first position. The first position may be one of an open position or a close position, and a second position is the other one of the open position or the close position; however, the following description defines the first position as an open position and the second position as a closed position. Since the topology includes a positive test switch 114p and a negative test switch 114n, the following description will refer to CASE 1 when discussing the positive test switch 114 p and CASE 2 when referring to the negative test switch 114n. Therefore, at block 304, instructions are made in CASE 1 to the positive test switch 114 p to be in the first position, i.e., the open position, while in CASE 2, instructions are made to the negative test switch 114n to be in the first position, i.e., the open position.

Following, at block 306, the method includes opening the chassis switch 212 of the sub-switch-circuit 210 which is connected to ground 106. At block 308, the method includes enabling the constant current source 214 of the sub-switch-circuit 210. By enabling the constant current source 214 a voltage difference occurs within the sub-switch-circuit 210 and at block 310, the method 300 includes measuring the resistor voltage V₂₁₆ across the resistor 216 of the sub-switch-circuit 210 by way of the ADC 118.

At decision block 312, the method 300 includes determining if the resistor voltage V₂₁₆ is equal to 0V. When the resistor voltage V₂₁₆ is not equal to 0V, then the method 300 determines at block 314 that the chassis switch 212 is stuck in the CLOSED position. In this case, the method 300 may stop isolation resistance monitoring and set an error flag immediately. In other examples, the method 300 may try to open/close the chassis switch 212 then execute the circuit check on the chassis switch 212. If the chassis switch 212 is still stuck open or close after several attempts, then the method 300 stops isolation resistance monitoring and set an error flag. However, when the resistor voltage V₂₁₆ is equal to 0V, then at block 316 the method 300 determines that the chassis switch 212 is still open.

Following block 316, at block 318, the method 300 includes disabling the constant current source 214 of the sub-switch-circuit 210. At block 320, the method 300 includes determining if the Voltage V₁₁₈ of the ADC 118 is equal to 0V. When the Voltage V₁₁₈ of the ADC 118 is not equal to 0V, then at block 322, the method 300 includes determining that the test switch 114, 114p, 114n is stuck in the second position, i.e., CLOSED position: in other words, in the first case, CASE 1, the positive test switch 114p is stuck in the second position, i.e., CLOSED position; while in the second case, CASE 2, the negative test switch 114 n is stuck in the close position. In this case, the method 300 may stop isolation resistance monitoring and set an error flag immediately. In other examples, the method 300 may try to open/close the negative test switch 114n then execute the circuit check on the negative test switch 114n. If the negative test switch 114n is still stuck open or close after several attempts, then the method 300 stops isolation resistance monitoring and set an error flag.

When the Voltage V₁₁₈ of the ADC 118 is equal to 0V, then at block 324, the method 300 includes determining that the test switch 114, 114p, 114n is in the open position, more specifically, in the first case, CASE 1, the positive test switch 114p is in the open position; while in the second case, CASE 2, the negative test switch 114n is in the open position.

Following block 324, at block 326, the method 300 includes closing the chassis switch 212. Then at block 328, the method 300 includes enabling the constant current source 214 of the sub-switch-circuit 210. At block 330, the method 300 includes measuring the resistor voltage V₂₁₆ across the resistor 216 of the sub-switch-circuit 210. At decision block 332, the method 300 includes determining if the resistor voltage V₂₁₆ is equal to 0V. When the resistor voltage V₂₁₆ is not equal to 0V, then the method 300 determines at block 334 the chassis switch 212 is stuck open. In this case, the method 300 may stop isolation resistance monitoring and set an error flag immediately. In other examples, the method 300 may try to open/close the chassis switch 212 then execute the circuit check on the chassis switch 212. If the chassis switch 212 is still stuck open or close after several attempts, then the method 300 stops isolation resistance monitoring and set an error flag.

When the resistor voltage V₂₁₆ is equal to 0V, i.e., then at block 336 the method determines that the chassis switch 212 is closed. Following, at block 338, the method 300 includes disabling the ADC 118 and completing the check when test switch 114 is open (i.e., CASE 1 and CASE 2).

Following at block 340, isolation monitoring is performed which is measuring the ADC 118 and HV battery pack voltage.

Once the method 300 completes the process for testing the test switch 114 while in the first position, then the method 300 proceeds with the check while the test switch 114 is in the second position.

At block 341, the method 300 includes instructing one of the test switches 114p, 114n to be in the second position. As previously mentioned, the second position is the other one of the open position or the close position. Since we established that the first position as described above is the open position, then the second position is a close position. At block 340, instructions are made in CASE 1 to the positive test switch 114p to be in the second position, i.e., the closed position, while in CASE 2, instructions are made to the negative test switch 114n to be in the second position.

Following, at block 342, the method 300 includes opening the chassis switch 212 of the sub-switch-circuit 210. At block 344, the method 300 includes enabling the constant current source 214 of the sub-switch-circuit 210. By enabling the constant current source 214 a voltage difference occurs within the sub-switch-circuit 210 and at block 346, the method 300 includes measuring the resistor voltage V₂₁₆ across the resistor 216 of the sub-switch-circuit 210 as discussed with respect to block 310.

At decision block 348, the method 300 includes determining if the resistor voltage V₂₁₆ is equal to 0V. When the resistor voltage V₂₁₆ not equal to 0V, then the method 300 determines at block 350 that the chassis switch 212 is stuck in the CLOSED position. In this case, the method 300 may stop isolation resistance monitoring and set an error flag immediately. In other examples, the method 300 may try to open/close the chassis switch 212 then execute the circuit check on the chassis switch 212. If the chassis switch 212 is still stuck open or close after several attempts, then the method 300 stops isolation resistance monitoring and set an error flag. However, when the resistor voltage V₂₁₆ is equal to 0V, then at block 352 the method 300 includes determining that the chassis switch 212 is still open.

Following, at block 354, the method 300 includes disabling the constant current source 214 of the sub-switch-circuit 210. At block 356, the method 300 includes determining if the voltage of the ADC 118 equal to 0V. When the ADC 118 voltage is equal to 0V, then the method 300 includes determining that the test switch 114, 114p, 114n is stuck in the first position, i.e., OPEN position: in other words, in the first case, CASE 1, the positive test switch 114p is stuck in the first position, i.e., OPEN position; while in the second case, CASE 2, the negative test switch 114 n is stuck in the OPEN position. When the voltage of the ADC 118 is not equal to 0V, then at block 360, the method 300 includes determining that the test switch 114, 114p, 114n is in the second position, i.e., CLOSE position, more specifically, in the first case, CASE 1, the positive test switch 114p is in the CLOSE position; while in the second case, CASE 2, the negative test switch 114n is in the CLOSE position.

At block 362, the method 300 includes closing the chassis switch 212, following at block 364, the method 300 includes enabling the constant current source 214 of the sub-switch-circuit 210. At block 366, the method 300 includes measuring the resistor voltage V₂₁₆ across the resistor 216 of the sub-switch-circuit 210. At decision block 368, the method 300 includes determining if the resistor voltage V₂₁₆ is equal to 0V. When the resistor voltage V₂₁₆ is not equal to 0V, the method 300 determines that the chassis switch 212 is stuck open as shown at 370. In this case, the method 300 may stop isolation resistance monitoring and set an error flag immediately. In other examples, the method 300 may try to open/close the chassis switch 212 then execute the circuit check on the chassis switch 212. If the chassis switch 212 is still stuck open or close after several attempts, then the method 300 stops isolation resistance monitoring and set an error flag.

When the resistor voltage V₂₁₆ is equal to 0V, i.e., then at block 372 the method 300 determines that the chassis switch 212 is closed. Following, at block 374, the method 300 includes disabling the ADC 118 and completing the check when test switch 114 is in the second position, i.e., closed position (i.e., CASE 1 and CASE 2). Following at block 390, the method 300 executes isolation monitoring which is measuring the ADC 118 and HV battery pack voltage.

FIG. 7A provides an example arrangement of operations for a method 400 of circuit check for isolation monitoring using the circuit of FIG. 2. At block 402, the method 400 includes providing an isolation monitoring circuit 110 to measure isolation resistance between high voltage domain and vehicle chassis. At block 404, the method 400 includes providing a test switch 114, 114p, 114n. the test switch 114, 114p, 114n is part of the isolation monitoring circuit 110. In some examples, the test switch 114, 114p, 114n includes a positive test switch 114p and a negative test switch 114n. The test switch 114, 114p, 114n is movable between a first test switch position (close/open) and a second test switch position (closed/open). At block 406, the method 400 includes providing a sub-switch-circuit 210. The sub-switch-circuit 210 includes a chassis switch 212, a constant current source 214, a resistor 216 positioned between the chassis switch 212, and a chassis ground 106. At block 408, the method 400 includes instructing the test switch 114, 114p, 114n to move to a first position. At block 440, the method 400 includes determining a current source voltage V₁₁₈. Additionally, at block 412, the method 400 includes determining a position of the test switch 114, 114p, 114n based on the current source voltage V₁₁₈.

In some implementations, the method 400 includes instructing the chassis switch 212 to move to an OPEN position and enabling the constant current source 214. In addition, the method 400 includes measuring a resistor voltage V₂₁₆ of the resistor 216. When the resistor voltage V₂₁₆ is equal to zero, the method 400 includes determining that the chassis switch 212 is in an OPEN position.

In some implementations, the method 400 includes instructing the chassis switch 212 to move to a CLOSE position and enabling the constant current source 214. Furthermore, the method 400 includes measuring a resistor voltage V₂₁₆ of the resistor 216. When the resistor voltage V₂₁₆ is not equal to zero, the method 400 includes determining that the chassis switch 212 is in the CLOSE position.

In some examples, when the current source voltage V₁₁₈ is equal to zero, the method 400 includes determining that the test switch 114, 114p, 114n is in an OPEN position: if the first test switch position is an OPEN position, the test switch 114, 114p, 114n is confirmed in the OPEN position, and if the first test switch position is a CLOSE position, the test switch 114, 114p, 114n is stuck in the OPEN position.

In some implementations, when the current source voltage V₁₁₈ is not equal to zero, the method 400 includes determining that the test switch 114, 114p, 114n is in a CLOSE position: if the first position is an OPEN position, the test switch 114, 114p, 114n is stuck in the CLOSE position, and if the first position is a CLOSE position, the test switch 114, 114p, 114n is confirmed in the CLOSE position.

In some examples, the method 400 includes disabling the constant current source 214 before determining the current source voltage V₁₁₈.

A number of implementations have been described. Nevertheless, it will be understood that various modifications may be made without departing from the spirit and scope of the disclosure. Accordingly, other implementations are within the scope of the following claims.

What is claimed is:

1. A method of circuit check for isolation monitoring, the method comprising:
providing an isolation monitoring circuit to measure isolation resistance between high voltage domain and vehicle chassis;
providing a test switch being part of the isolation monitoring circuit, the test switch being movable between a first test switch position and a second test switch position;
providing a sub-switch-circuit comprising a chassis switch, a constant current source, a resistor positioned between the chassis switch, and a chassis ground;
instructing the test switch to move to a first position;
determining a current source voltage; and
determining a position of the test switch based on the current source voltage.

2. The method of claim 1, further comprising:
instructing the chassis switch to move to an OPEN position;
enabling the constant current source;
measuring a resistor voltage of the resistor;
when the resistor voltage is equal to zero, determining that the chassis switch is in an OPEN position.

3. The method of claim 1, further comprising:
instructing the chassis switch to move to a CLOSE position;
enabling the constant current source;
measuring a resistor voltage of the resistor;
when the resistor voltage is not equal to zero, determining that the chassis switch is in the CLOSE position.

4. The method of claim 1, further comprising:
when the current source voltage is equal to zero, determining that the test switch is in an OPEN position, wherein:
if the first test switch position is an OPEN position, the test switch is confirmed in the OPEN position, and
if the first test switch position is a CLOSE position, the test switch is stuck in the OPEN position.

5. The method of claim 1, further comprising:
when the current source voltage is not equal to zero, determining that the test switch is in a CLOSE position, wherein
if the first position is an OPEN position, the test switch is stuck in the CLOSE position, and
if the first position is a CLOSE position, the test switch is confirmed in the CLOSE position.

6. The method of claim 1, further comprising:
disabling the constant current source before determining the current source voltage.

7. The method of claim 1, wherein the test switch includes a positive test switch and a negative test switch.

8. A circuit for isolation monitoring and circuit checking, the circuit comprising:
an isolation monitoring circuit to measure isolation resistance between high voltage domain and vehicle chassis;
a test switch being part of the isolation monitoring circuit, the test switch being movable between a first test switch position and a second test switch position;
a sub-switch-circuit comprising a chassis switch, a constant current source, a resistor positioned between the chassis switch, and a chassis ground;
a controller in communication with the isolation monitoring circuit and the sub-switch-circuit, the controller configured to:
instruct the test switch to move to a first position;
determine a current source voltage; and
determine a position of the test switch based the current source voltage.

9. The circuit of claim 8, wherein the controller is further configured to:
instruct the chassis switch to move to an OPEN position;
enable the constant current source;
measure a resistor voltage of the resistor;
when the resistor voltage is equal to zero, determine that the chassis switch is in an OPEN position.

10. The circuit of claim 8, wherein the controller is further configured to:
instruct the chassis switch to move to a CLOSE position;
enable the constant current source;
measure a resistor voltage of the resistor;
when the resistor voltage is not equal to zero, determine that the chassis switch is in the CLOSE position.

11. The circuit of claim 8, wherein the controller is further configured to:
when the current source voltage is equal to zero, determine that the test switch is in an open position, wherein:
if the first test switch position is an OPEN position, the test switch is confirmed in the OPEN position, and
if the first test switch position is a CLOSE position, the test switch is stuck in the OPEN position.

12. The circuit of claim 8, wherein the controller is further configured to:
when the current source voltage is not equal to zero, determine that the test switch is in a close position, wherein
if the first position is an OPEN position, the test switch is stuck in the close position, and
if the first position is a CLOSE position, the test switch is confirmed in the CLOSE position.

13. The circuit of claim 8, wherein the controller is further configured to:
disable the constant current source before determining the current source voltage.

14. The circuit of claim 8, wherein the test switch includes a positive test switch and a negative test switch.
